(19) United States
(12) Patent Application Publication
(10) Pub. No.: US 2013/0070546 A1
(43) Pub. Date: Mar. 21, 2013

(54) NONVOLATILE SEMICONDUCTOR MEMORY DEVICE

(71) Applicants: Osamu Nagao, Yokohama-shi (JP); Hitoshi Shiga, Kawasaki-shi (JP)

(72) Inventors: Osamu Nagao, Yokohama-shi (JP); Hitoshi Shiga, Kawasaki-shi (JP)

(73) Assignee: Kabushiki Kaisha Toshiba, Tokyo (JP)

(21) Appl. No.: 13/423,759

(22) Filed: Mar. 19, 2012

(30) Foreign Application Priority Data
Sep. 16, 2011 (JP) 2011-203401

(51) Int. Cl. G11C 29/44

(52) U.S. Cl. 365/200

(57) ABSTRACT

A nonvolatile semiconductor memory device according to the embodiment comprises a memory cell array including plural blocks arranged in a first direction, each block containing plural memory cells operative to store data; a row decoder including a faulty block information holder circuit operative to store faulty block information indicative that the block is a faulty block; and a faulty block detector circuit operative to, when each of block groups includes at least one of the plural blocks, subject one of the block groups to a first detection step of simultaneously and intensively referring to pieces of faulty block information respectively corresponding to the plural blocks in one of the block groups simultaneously to detect whether the block group contains a faulty block.

### CROSS-REFERENCE TO RELATED APPLICATIONS

This application is based upon and claims the benefit of priority from the prior Japanese Patent Application No. 2011-203401, filed on Sep. 16, 2011, the entire contents of which are incorporated herein by reference.

### FIELD

The embodiment relates to a nonvolatile semiconductor memory device.

### BACKGROUND

As the electrically erasable programmable and highly integrated nonvolatile semiconductor memory device, a NAND-type flash memory has been known. Hereinafter, the NAND-type flash memory is described as an example.

Usually, in the NAND-type flash memory, faulty blocks in production steps are allowed to occur up to a point. As for the occurred faulty blocks, the addresses thereof are registered in an area in a memory cell array, thereby restricting access from the user.

The address of the faulty block is registered at the product test step. In the conventional registration method, a faulty block is detected at every block. Accordingly, the processing time for the product test increases.

### BRIEF DESCRIPTION OF THE DRAWINGS

FIG. 1 is a block diagram of a nonvolatile semiconductor memory device according to a first embodiment.

FIG. 2 provides a circuit diagram of a memory cell array in the nonvolatile semiconductor memory device according to the same embodiment and a block diagram of the periphery thereof.

FIG. 3 is a circuit diagram of a portion of a row decoder in the nonvolatile semiconductor memory device according to the same embodiment.

FIG. 4 is a circuit diagram of a faulty block detector circuit in the nonvolatile semiconductor memory device according to the same embodiment.

FIG. 5 is a flowchart of faulty block detection and registration processing in the nonvolatile semiconductor memory device according to the same embodiment.

FIG. 6 provides a table showing the relation between the block failure rate and the processing time when faulty block detecting operation is used in the nonvolatile semiconductor memory device according to the same embodiment.

FIG. 7 is a block diagram of a block selection signal masking circuit in a nonvolatile semiconductor memory device according to a second embodiment.

### DETAILED DESCRIPTION

A nonvolatile semiconductor memory device according to the embodiment comprises a memory cell array including plural blocks arranged in a first direction, each block containing plural memory cells operative to store data; a row decoder including a faulty block information holder circuit operative to store faulty block information indicative that the block is a faulty block; and a faulty block detector circuit operative to, when each of block groups includes at least one of the plural blocks, subject one of the block groups to a first detection step of simultaneously and intensively referring to pieces of faulty block information respectively corresponding to the plural blocks in one of the block groups simultaneously to detect whether the block group contains a faulty block.

Nonvolatile semiconductor memory devices according to the embodiments will now be described below with reference to the drawings.

### First Embodiment

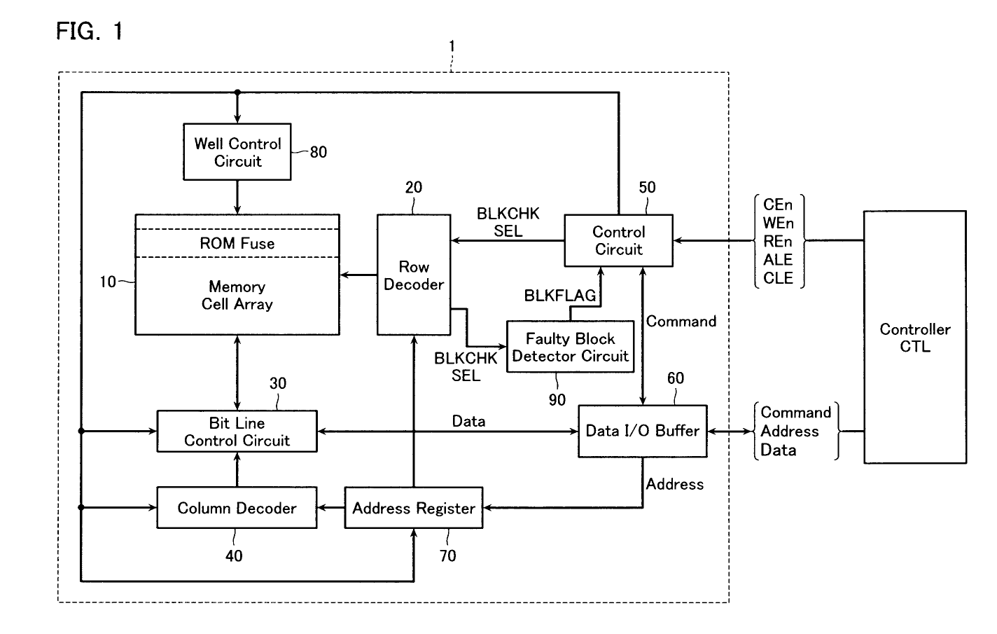

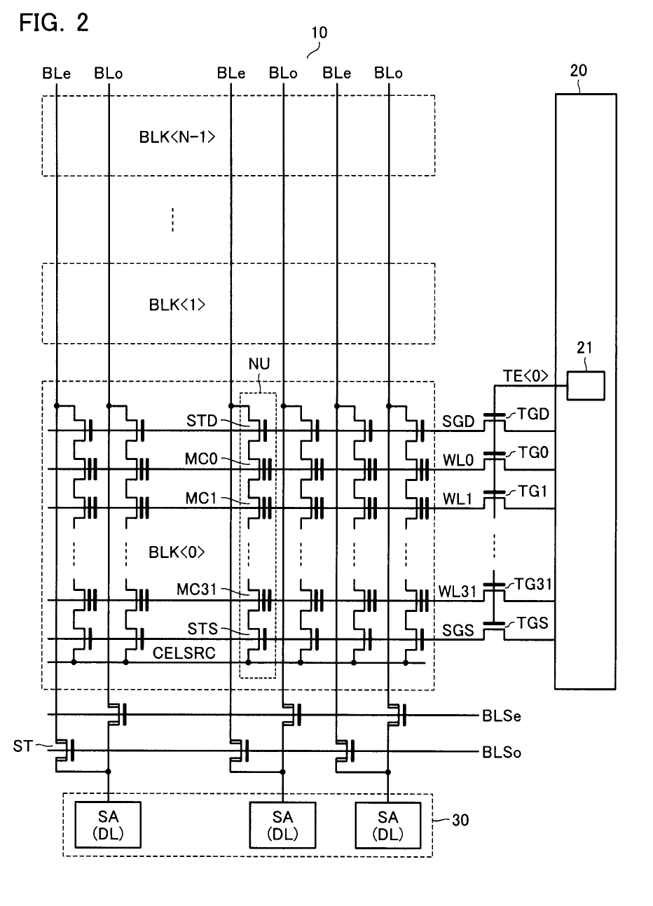

FIG. 1 is a block diagram of a nonvolatile semiconductor memory device according to a first embodiment, that is, a NAND-type flash memory. FIG. 2 provides a circuit diagram of a memory cell array 10 shown in FIG. 1 and a block diagram of the peripheral circuit thereof.

The memory cell array 10 includes plural NAND cell units NU, each of which is a basic unit of the NAND-type flash memory. These NAND cell units NU each include serially connected plural memory cells MC0-MC31 and 2 selection transistors STD, STS arranged on both ends thereof. The NAND cell unit NU has one end connected via the selection transistor STD to a bit line BL (BLe or BLo), and the other end connected via the selection transistor STS to a source line CELSRC common in the memory cell array 10. Usually, plural NAND cell units NU are arranged in the direction of extension of the word line WL, that is, the row direction as shown in FIG. 2. It is described in FIG. 2 as an example that the number of memory cells MC is equal to 32. The number of memory cells MC is not limited to 32 but rather may be equal to 16, 64, or 128. One or plural dummy cells DMC may be located between the memory cells MC and the selection transistors STD, STS.

The memory cell MC comprises a MOS transistor, for example, which has an N-type source/drain diffusion layer, and a stacked gate including a charge accumulating layer (e.g. a floating gate or insulating film with charge trap) and a control gate. The quantity of charge held in the charge accumulating layer can be varied by operations of writing and erasing, thereby varying the threshold voltage of the memory cell MC to store data nonvolatilely. The control gates of the memory cells MC in the NAND cell unit NU are connected to the word lines WL0-WL31, respectively. The gates of the selection transistors STS, STD are connected to selection gate lines SGD, SGS, respectively. A set of the NAND cell units NU sharing the word lines WL0-WL31 and selection gate lines SGD, SGS forms a block BLK, that is, a unit of data batch erasing. Usually, plural blocks BLK<0>, BLK<1>, . . . , BLK<N−1> (N is an integer of 1 or more) are arranged in the direction of extension of the bit line BL, that is, the column direction as shown in FIG. 2. It is described in FIG. 2 as an example that the number of word lines WL is equal to 32. The number of word lines WL is not limited to 32 similar to the memory cells MC.

A row decoder 20 selects a block BLK in accordance with the address, and selects and drives the word lines WL0-WL31 and selection gate lines SGD, SGS in the selected block BLK.

A bit line control circuit 30 includes sense amps SA for 1 page. The bit line control circuit 30 and the memory cell array 10 transfer read/write data therebetween in batch on a page basis.

A column decoder 40 selects write/read data column by column. Thus, the read/write data is subject to serial data transfer between the bit line control circuit 20 and an external input/output terminal.

A control circuit 50 controls the row decoder 20, the bit line control circuit 30, the column decoder 40, a data input/output buffer 60, an address register 70 and a well control circuit 80 to realize various operations of the nonvolatile semiconductor memory device. For example, based on the external control signals (such as the chip enable CEn, the write enable WEn, the read enable REn, the address latch enable ALE and the command latch enable CLE) and the commands given from the external input/output terminal, operations at the time of data writing, erasing and reading are a part thereof.

The data input/output buffer 60 receives commands and addresses given from the external input terminal (e.g. an electrode pad), and sends/receives data sent from the bit line control circuit 30 or data given from the external input/output terminal. The command, address and data given from the external input/output terminal are sent to the control circuit 50, the bit line control circuit 30 and the address register 70, respectively.

The address register 70 generates a row address and a column address based on the address received from the data input/output buffer 60, and sends them to the row decoder 20 and the column decoder 40, respectively. The row decoder 20 and the column decoder 40 select an access-targeted memory cell MC based on the row address and the column address.

The well control circuit 80 applies voltages required for data erasing, writing and reading to a well of the memory cell MC.

A faulty block detector circuit 90 is a circuit operative to specify a block BLK having a malfunction (hereinafter referred to as a “faulty block”) after a die sort test, that is, one of the product test steps. The address of the specified faulty block (hereinafter referred to as a “faulty block address”) is registered in a ROM fuse area in the memory cell array 10 by the control circuit 50. The information on the faulty block may be held not in the ROM fuse area but in a controller CTL outside the NAND chip 1. The faulty block detector circuit 90 receives a block detection signal BLKCHK and a block selection signal SEL sent from the control circuit 50 via the row decoder 20. The faulty block detector circuit 90 is activated by the block detection signal BLKCHK to detect if the block BLK selected by the block selection signal SEL is a faulty block. The detection result is sent to the control circuit 50 as a block flag BLKFLAG.

The block flag BLKFLAG is a signal that turns to ‘H’ (such as the supply voltage Vdd) if the detection target block BLK is not a faulty block or if plural detection target blocks BLK contain no faulty block. The signal turns to ‘L’ (such as the ground voltage Vss) if the detection target block BLK is a faulty block or if plural detection target blocks BLK contain a faulty block.

The row decoder 20 is described next in detail.

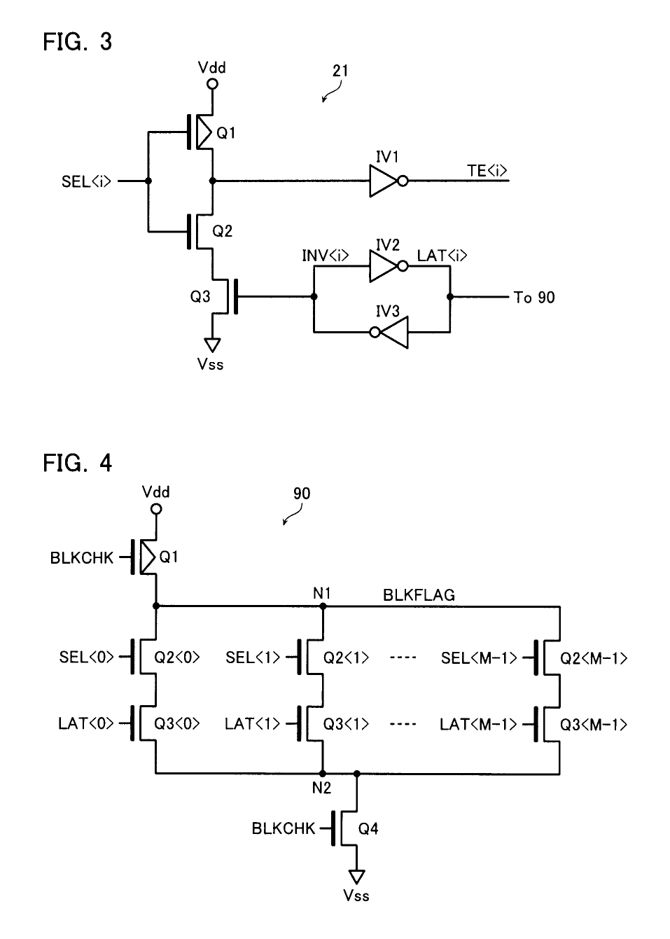

The row decoder 20 includes a unit circuit 21 shown in FIG. 3 at every block BLK in the memory cell array 10.

The unit circuit 21 comprises a PMOS transistor Q1, NMOS transistors Q2, Q3, and inverters IV1, IV2 and IV3.

Among those, the transistors Q1, Q2 and Q3 are serially connected between the supply voltage Vdd and the ground voltage Vss. The gates of the transistors Q1 and Q2 are connected in common to receive a block selection signal SEL<i> (i is an integer of 0 to N−1). The connection node between the transistors Q1 and Q2 is connected to the input of the inverter IV1. The output from the inverter IV1 provides a transfer gate enable signal TE<i>.

The transfer gate enable signal TE<i> is a signal that activates transfer gates TGD, TG0-TG31 and TGS provided between the row decoder 2 and the selection gate line SGD, the word lines WL0-WL31 and the selection gate line SGS, respectively, as shown in FIG. 2. When this signal turns to ‘H’, the row decoder 2 is electrically connected to the selection gate line SGD, the word lines WL0-WL31 and the selection gate line SGS.

The inverter IV2 and the inverter IV3 have inputs and outputs, which are cross-connected to configure a latch circuit (faulty block information holder circuit). The output from the inverter IV2 provides a latch signal LAT<i>. The output from the inverter IV3 provides an inverter signal INV<i> in reverse of the latch signal LAT<i>. This inverter signal INV<i> is fed to the gate of the transistor Q3.

The latch signal LAT<i> is indicative that a block BLK<i> is a faulty block. It is a signal that turns to ‘H’ if the block is a faulty block and ‘L’ if not. Naturally, the inverter signal INV exhibits the opposite state thereto. Hereinafter, the latch signal LAT<i> and the inverter signal INV<i> may also be referred to as “faulty block information” on the block BLK<i>.

Subsequently, operation of the unit circuit 21 is described briefly.

If the block BLK<i> is not a faulty block, the latch signal LAT<i> is at ‘L’ and the inverter signal INV<i> is at ‘H’. In this state, when the control circuit 50 selects the block BLK<i>, the block selection signal SEL<i> at ‘H’ turns the input to the inverter IV1 to ‘L’ and the transfer gate enable signal TE<i> to ‘H’. As a result, the transfer gates TGD, TG0-TG31 and TGS turn on, thereby electrically connecting the row decoder 2 with the selection gate line SGD, the word lines WL0-WL31 and the selection gate line SGS in the block BLK<i>. In contrast, unless the control circuit 50 selects the block BLK<i>, the transfer gates TGD, TG0-TG31 and TGS turn off. Therefore, the row decoder 20 is electrically disconnected from the selection gate line SGD, the word lines WL0-WL31 and the selection gate line SGS in the block BLK<i>.

On the other hand, if the block BLK<i> is a faulty block, the latch signal LAT<i> is at ‘H’ and the inverter signal INV<i> is at ‘L’, which turns off the transistor Q3. Therefore, even if the block selection signal SEL<i> turns to ‘H’, the transfer gate enable signal TE cannot turn to ‘H’. As a result, the row decoder 20 is electrically disconnected from the selection gate line SGD, the word lines WL0-WL31 and the selection gate line SGS in the block BLK<i>.

In a word, if the corresponding block BLK<i> is not selected or if it is a faulty block, the unit circuit 21 shown in FIG. 3 makes it possible to isolate the selection gate line SGD, the word lines WL0-WL31 and the selection gate line SGS from the output voltage from the row decoder 20.

The faulty block detector circuit 90 is described next in detail.

The faulty block detector circuit 90 comprises a PMOS transistor Q1, M sets (M is an integer of N or less) of NMOS transistors Q2<j> and Q3<j> (j is an integer of 0 to M−1), and an NMOS transistor Q4 as shown in FIG. 4.

The transistors Q2<j> and Q3<j> are serially connected at every set to form current paths. These current paths are connected in parallel between a node N1 (first node) and a node N2 (second node). In a word, if the transistors Q2<j> and Q3<j> both turn on in even one serial circuit, the node N1 is electrically connected to the node N2. The gates of the transistors Q2<j> and Q3<j> receive the block selection signal SEL<j> and the latch signal LAT<j>, respectively.

The transistor Q1 is connected between the supply voltage Vdd (first voltage) and the node N1. The transistor Q4 is connected between the ground voltage Vss (second voltage) and the node N2. The gates of these transistors Q1 and Q4 each receive the block detection signal BLKCHK.

In accordance with the configuration shown in FIG. 4, the node N1 provides the output from the faulty block detector circuit 90, that is, the block flag BLKFLAG.

Subsequently, operation of the faulty block detector circuit 90 is described briefly.

For example, when it detects if one block BLK<j> is a faulty block, the faulty block detector circuit 90 operates as follows.

At the time of faulty block detecting operation, the control circuit 5 turns the block detection signal BLKCHK to ‘H’. Thus, the node NA1 is connected to the supply voltage Vdd and the node NA2 to the ground voltage Vss.

In this state, it turns the block selection signal BLK<j> for selection of the block BLK<j> to ‘H’ and other block selection signals SEL<k> (k is an integer of 0 to M−1 except j) to ‘L’. Thus, the transistors Q2<k> turn off and the transistor Q2<j> turns on. As a result, the presence/absence of conduction between the node N1 and the node N2 depends on the latch signal LAT<j> for control of the transistor Q3<j>. In other words, the status of the block flag BLKFLG varies based on the faulty block information on the detection target block BLK<j>.

Specifically, if the block BLK<j> is a faulty block, the block selection signal SEL<j> and the latch signal LAT<j> turn to ‘H’. Therefore, the transistors Q2<j> and Q3<j> both turn on and pull the level of the node NA1 down to the ground voltage Vss. In a word, the block flag BLKFLAG turns to ‘L’.

On the other hand, unless the block BLK<j> is a faulty block, the transistor Q2<j> turns off. Therefore, the level of the node NA1 is still kept at the supply voltage Vdd. In a word, the block flag BLKFLAG turns to ‘H’.

Thus, in accordance with the faulty block detector circuit 90 shown in FIG. 4, turning the block selection signal BLK<j> to ‘H’ makes it possible to detect if the block BLK<j> is a faulty block.

Therefore, with sequential increments of j from 1, faulty block detecting operation can be executed over all blocks BLK.

The above description is given to faulty block detecting operation on one block BLK<j> while the following description is given to operation in the embodiment of the present invention. The faulty block detector circuit 90 shown in FIG. 4 is also possible to execute faulty block detecting operation over plural blocks BLK<j> at the same time. Hereinafter, a group of blocks BLK<j> subject to faulty block detecting operation at the same time may also be referred to as a “block group”. The NAND chip 1 contains plural such block groups and arranges faulty block detector circuits 90 corresponding to respective block groups.

For example, blocks BLK<0>-<M−1> are grouped into one block group. When it is intended to detect if the block group contains a faulty block, the block detection signal BLKCHK is turned to ‘H’ and the block selection signals SEL<0>-<M−1> are turned to ‘H’. In this case, the transistors Q2<0>-<M−1> turn on. As a result, the block flag BLKFLAG turns to ‘L’ if any one of pieces of faulty block information on the blocks BLK<0>-<M−1>, that is, the latch signals LAT<0>-<M−1> is at ‘H’, and remains at ‘H’ unchanged if they are all at ‘L’. In a word, referring to the status of the block flag BLKFLAG makes it possible to detect if the block group contains a faulty block.

Thus, when the latch signals LAT corresponding to plural blocks BLK in a block group are not referred to individually but referred to simultaneously and intensively, the processing time can be made shorter than when the faulty block detecting operation is sequentially executed to one block BLK individually.

If the faulty block detecting operation is executed at every block group, it is possible to detect if a block group contains a faulty block. It is not possible, though, to detect which block BLK is the faulty block.

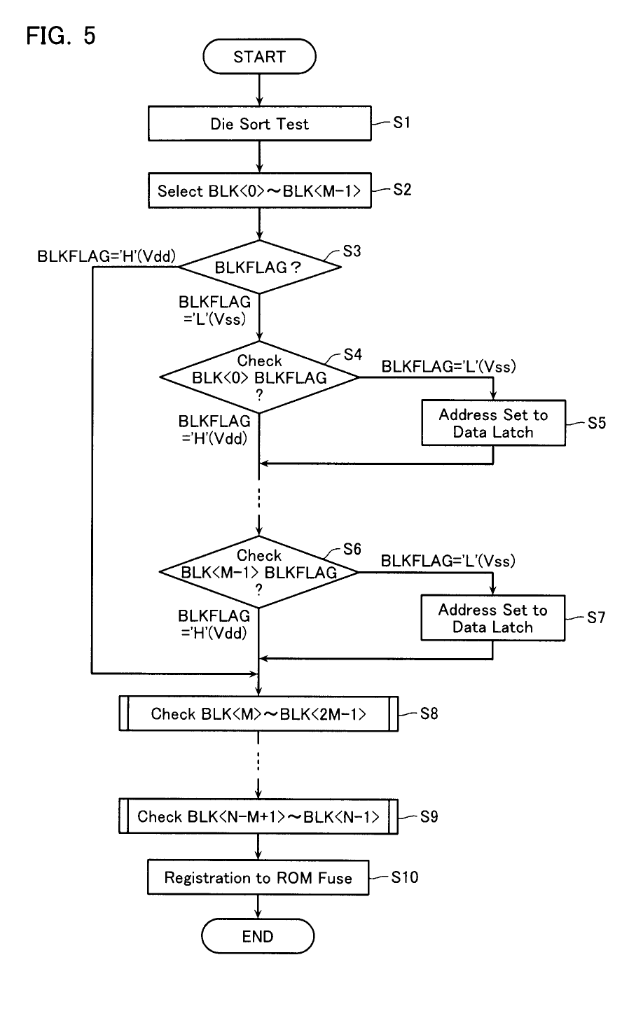

Therefore, the present embodiment advances processing of faulty block detection and registration in a product test as in FIG. 5.

In the product test of the present embodiment, at the first step S1, a die sort test is executed. In the die sort test, the latch circuit contained in the unit circuit 21 in the row decoder 20 stores faulty block information on the block BLK corresponding to each unit circuit 21 as the latch signal LAT<i>.

Subsequently, as a first detection step, a block group of blocks BLK<0>-<M−1> is selected to execute faulty block detecting operation to the block group (step S2). Specifically, the control circuit 50 turns the block check signal BLKCHK for the faulty block detector circuit 90 to ‘H’ and receives the block selection signal and faulty block information from the row decoder 20. As a result, the block selection signals SEL<0>-<M−1> for the faulty block detector circuit 90 all turn to ‘H’. If the block flag BLKFLAG is at ‘H’ (the supply voltage Vdd), that is, if the block group contains no faulty block, the flow shifts processing to step S8 for executing faulty block detecting operation to the next block group. On the other hand, if the block flag BLKFLAG is at ‘L’ (the ground voltage Vss), that is, if the block group contains a faulty block, the flow shifts processing to step S4 for detecting if the block BLK in this block group is a faulty block (step S3).

Subsequently, at steps S4-S7, as a second detection step, faulty block detecting operation is executed to each block BLK in the block group.

At step S4, faulty block detecting operation is executed to the first block BLK<0> in the block group. Specifically, the block check signal BLKCHK is turned to ‘H’, and the block selection signal SEL<0> is turned to ‘H’ while the block selection signals SEL<1>-<M−1> to ‘L’. As a result, if the block flag BLKFLAG is at ‘H’ (the supply voltage Vdd), that is, if the block BLK<0> is not a faulty block, the flow shifts processing to faulty block detecting operation to the next block BLK<1> (not shown). On the other hand, if the block flag BLKFLAG is at ‘L’ (the ground voltage Vss), that is, if the block BLK<0> is a faulty block, the flow shifts processing to step S5.

At step S5, the address of the block BLK<0> is registered as a faulty block address in the ROM fuse area in the memory cell array 10. For that purpose, the address of the block BLK<0> is set in the data latch DL in the bit line control circuit 3.

Similar to these steps S4 and S5, faulty block detecting operation to each block BLK is sequentially executed until steps S6 and S7.

In accordance with the above steps S4-S7, it is made possible to detect which block BLK in the block group is a faulty block.

Thereafter, similar processing to steps S2-S7 are executed to a block group of blocks BLK<M>-<2M−1> (step S8), . . . , a block group of blocks BKL<N−M+1>-<N−1> (step S9).

Finally, at step S10, the faulty block address saved in the data latch DL is registered (stored) in the ROM fuse area.

Through the above flow, faulty block detecting and detecting operation over all the blocks BLK<0>-<N−1> can be completed.

Thus, the present embodiment combines the first detection step of detecting the presence/absence of a faulty block at every block group and the second detection step of detecting at every block BLK if the block corresponds to the faulty block only in the block group containing the faulty block. Therefore, in comparison with the execution of faulty block detecting operation over all blocks BLK at every block BLK (hereinafter such the faulty block detection and registration processing is referred to as “faulty block detection and registration processing according to a comparison example”), it is possible to execute faulty block detection and registration processing faster.

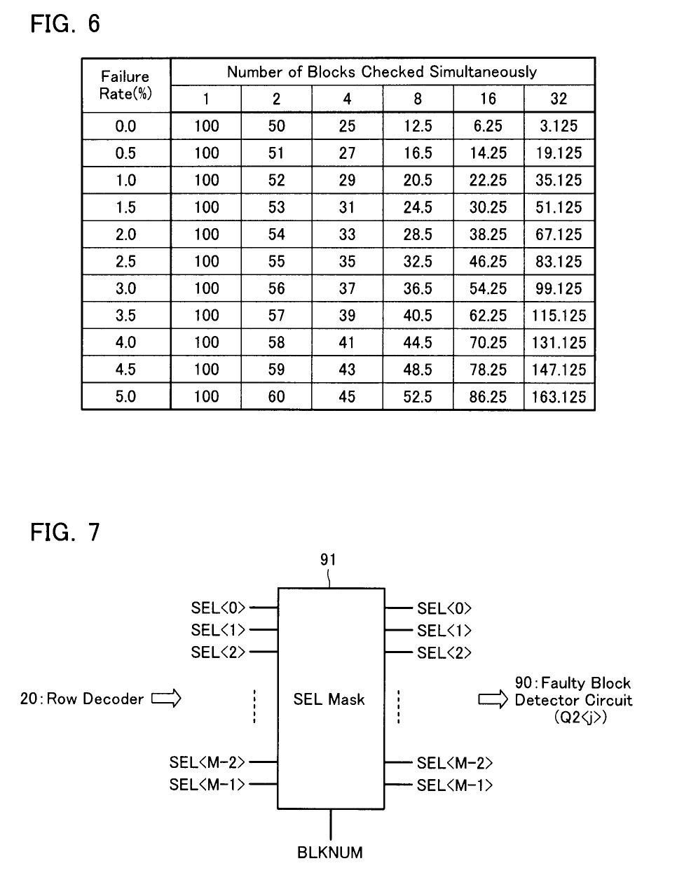

FIG. 6 provides a table showing the relation between the failure rate, which is a proportion of faulty blocks to all blocks, and the time for faulty block detection and registration processing. The numeral in FIG. 6 indicates the relative time on the basis of 100, that is, the time for faulty block detection and registration processing according to the comparison example. For simplification, computation is executed on condition that only 1 faulty block appears in 1 block group. From this point, the processing time in the present embodiment shown in FIG. 6 indicates the worst value.

As shown in FIG. 6, between the failure rates of 0-5%, the present embodiment is generally possible to execute processing in shorter time than the comparison example as can be found. For example, in the case of the failure rates of 3.5% or more, if the number of blocks in a block group is equal to 32, the present embodiment takes longer time than the comparison example. In consideration of actual NAND-type flash memories, however, the failure rate is not so high and accordingly it is not problematic in practice. Even if the failure rate is high, setting the number of blocks in a block group smaller to a point makes it possible to achieve a shorter processing time than the comparison example.

Thus, the present embodiment is possible to provide a nonvolatile semiconductor memory device capable of processing faulty block detection and registration in a product test in shorter time than the comparison example.

### Second Embodiment

In the nonvolatile semiconductor memory device according to the first embodiment, the number of blocks in a block group is fixed. In contrast, a second embodiment describes a nonvolatile semiconductor memory device capable of easily setting the number of blocks in a block group.

The nonvolatile semiconductor memory device according to the present embodiment further comprises a block selection signal masking circuit 91 (block number adjuster circuit) shown in FIG. 7 in addition to the configuration similar to the nonvolatile semiconductor memory device according to the first embodiment. The block selection signal masking circuit 91 masks the block selection signals SEL supplied to the transistors Q2<j> in the faulty block detector circuit 90 in accordance with a block number setting signal BLKNUM sent from the control circuit 50.

For example, the block number setting signal BLKNUM designates 8 as the number of blocks in a block group. In this case, as for the block selection signals SEL<0>-<7>, the block selection signal masking circuit 91 provides the received block selection signals SEL<0>-<7> directly to the transistors Q2 in the faulty block detector circuit 90. As for the block selection signals SEL<8>-<M−1>, the block selection signal masking circuit 91 provides ‘L’ to the transistors Q2 in the faulty block detector circuit 90.

As a result, the transistors Q2<8>-<M−1> in the faulty block detector circuit 90 turn off independent of the states of the block selection signals SEL<8>-<M−1> sent from the control circuit 50. In a word, it is possible to limit the faulty block detection target to 8 blocks BLK<0>-<7>.

Thus, the addition of the block selection signal masking circuit 91 makes it possible to adjust the number of blocks in a block group to an optimal value in accordance with the failure rate.

In a word, the present embodiment is possible to provide a nonvolatile semiconductor memory device capable of optimally and easily adjusting the scale of a block group so that the effect exerted by the first embodiment can be made larger.

The block selection signal masking circuit 91 may be contained in the faulty block detector circuit 90 or may be configured different from the faulty block detector circuit 90.

### [Others]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a memory cell array including plural blocks arranged in a first direction, each block containing plural memory cells operative to store data;
a row decoder including a faulty block information holder circuit operative to store faulty block information indicative that said block is a faulty block; and
a faulty block detector circuit operative to, when each of block groups includes at least one of said plural blocks, subject one of said block groups to a first detection step referring to pieces of faulty block information corresponding to said plural blocks in one of said block groups simultaneously to detect whether said block group contains a faulty block.

2. The nonvolatile semiconductor memory device according to claim 1, wherein said faulty block detector circuit, when it detects that one of said block groups contains a faulty block at said first detection step, subjects said plural blocks in one of said block groups to a second detection step detecting whether each block corresponds to a faulty block based on said faulty block information corresponding to said block sequentially.

3. The nonvolatile semiconductor memory device according to claim 1, wherein said faulty block detector circuit detects whether one of said block groups contains a faulty block at said first detection step based on a block selection signal and said faulty block information corresponding to each blocks in one of said block group, received from said row decoder.

4. The nonvolatile semiconductor memory device according to claim 3, wherein said faulty block detector circuit includes plural current paths connected in parallel between a first node and a second node, and
said current path serially connects a first transistor supplied with said block selection signal to a second transistor supplied with said faulty block information.

5. The nonvolatile semiconductor memory device according to claim 4, wherein said first node is charged to a first voltage and said second node is electrically connected to a second voltage different from said first voltage, and
said faulty block detector circuit detects whether one of said block groups contains a faulty block in accordance with a variation in voltage on said first node.

6. The nonvolatile semiconductor memory device according to claim 1, further comprising a block number adjuster circuit operative to adjust the number of blocks belonging to said block groups.

7. The nonvolatile semiconductor memory device according to claim 1, further comprising a transfer gate operative to electrically connect between one of said plural blocks and said row decoder,
wherein said row decoder generates a transfer gate enable signal for control of said transfer gate based on said faulty block information.

8. The nonvolatile semiconductor memory device according to claim 2, wherein a portion of memory cells in said memory cell array is a ROM fuse area used to register the address of a faulty block specified at said second detection step.

9. A nonvolatile semiconductor memory device, comprising:
a memory cell array including plural blocks arranged in a first direction, each block containing plural memory cells operative to store data;
a row decoder including a faulty block information holder circuit operative to store faulty block information indicative that said block is a faulty block; and
a faulty block detector circuit include plural current paths connected in parallel between a first node charged to a first voltage and a second node set on a second voltage different from said first voltage, and configured to be controlled by faulty block information on each block in said block group when each of block groups includes at least one of said plural blocks.

10. The nonvolatile semiconductor memory device according to claim 9, wherein said faulty block detector circuit detects whether said block group contains a faulty block in accordance with a variation in voltage on said first node.

11. The nonvolatile semiconductor memory device according to claim 9, wherein said current path includes a first transistor and a second transistor serially connected,
said first transistor is controlled by a block selection signal for selection of said block, and
said second transistor is controlled by said faulty block information corresponding to said block.

12. The nonvolatile semiconductor memory device according to claim 9, further comprising a block number adjuster circuit operative to adjust the number of turn-on intended second transistors of the second transistors contained in said current paths in accordance with said block selection signal.

13. The nonvolatile semiconductor memory device according to claim 9, further comprising a transfer gate operative to electrically connect between one of said plural blocks and said row decoder,
wherein said row decoder generates a transfer gate enable signal for control of said transfer gate based on said faulty block information.

14. A nonvolatile semiconductor memory device, comprising:
a memory cell array including plural blocks arranged in a first direction, each block containing plural memory cells operative to store data;
a row decoder including a faulty block information holder circuit operative to hold faulty block information indicative that said block is a faulty block; and
a faulty block detector circuit operative to, when each of block groups includes at least one of said plural blocks, subject one of said block groups containing said faulty block to sequentially detecting whether each block in said block group corresponds to a faulty block based on said faulty block information corresponding to said block.

15. The nonvolatile semiconductor memory device according to claim 14, wherein said faulty block detector circuit detects whether one of said plural blocks corresponds to a faulty block based on a block selection signal and said faulty block information corresponding to one of said plural blocks.

16. The nonvolatile semiconductor memory device according to claim 14, wherein said faulty block detector circuit includes plural current paths connected in parallel between a first and a second node, and
said current path serially connects a first transistor supplied with said block selection signal to a second transistor supplied with said faulty block information.

17. The nonvolatile semiconductor memory device according to claim 14, wherein said first node is charged to a first voltage and said second node is electrically connected to a second voltage different from said first voltage, and
said faulty block detector circuit detects whether said block corresponds to said faulty block in accordance with a variation in voltage on said first node.

18. The nonvolatile semiconductor memory device according to claim 14, further comprising a block number adjuster circuit operative to adjust the number of blocks belonging to one of said block groups.

19. The nonvolatile semiconductor memory device according to claim 14, further comprising a transfer gate operative to electrically connect between one of said plural blocks and said row decoder,
wherein said row decoder generates a transfer gate enable signal for control of said transfer gate based on said faulty block information.

20. The nonvolatile semiconductor memory device according to claim 14, wherein a portion of memory cells in said memory cell array forms a ROM fuse area used to register the address of said faulty block.
